(19) United States
(12) Patent Application Publication
(10) Pub. No.: US 2007/0173070 A1
(43) Pub. Date: Jul. 26, 2007

(54) POROUS LOW-K DIELECTRIC FILM AND FABRICATION METHOD THEREOF

(76) Inventors: Mei-Ling Chen, Kao-Hsiung City (TW); Su-Jen Sung, Hsin-Chu Hsien (TW); Kuo-Chih Lai, Tai-Nan City (TW); Jei-Ming Chen, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/307,167

(22) Filed: Jan. 26, 2006

(51) Int. Cl. H01L 21/31

(52) U.S. Cl. 438/778

(57) ABSTRACT

A method for fabricating a porous low-k dielectric film includes providing a substrate, performing a first CVD process by providing a back-bone precursor to form an interface dielectric layer, performing a second CVD process by providing a porogen precursor to form a back-bone layer, and removing the porogens in the back-bone layer so that the back-bone layer becomes an ultra low-k dielectric layer. The interface dielectric layer and the ultra low-k dielectric layer compose a porous low-k dielectric film.

### BACKGROUND OF THE INVENTION

1. Field of the Invention

The invention relates to a low-k film structure of a semiconductor device and fabrication method thereof, and more particularly, to a porous ultra low-k film structure and fabrication method thereof.

2. Description of the Prior Art

As the integration of semiconductor devices increases, the distance between adjacent devices on a semiconductor wafer is shortened to cause various problems. For example, if one conductor is in very close proximity to another conductor and an inter-layer dielectric (ILD) layer is filled between the two conductors, the two conductors and the ILD layer naturally form a capacitor. In any circuit, the resistor-capacitance (RC) delay effects occur when a capacitor exists to result in the slowing down of delivery of signals for a period of time.

Traditionally, the material of choice for the ILD is silicon dioxide (SiO₂) which can be prepared using silane or siloxane precursors in an oxidizing environment. The popular deposition techniques for depositing ILD are chemical vapor deposition (CVD), low temperature plasma-enhanced CVD (PECVD), or high density plasma CVD (HDPCVD). However, the dielectric constant of the deposited silicon dioxide is relatively high at 4.0.

For sub-micron technology, or even for 65 nm and 45 nm node or beyond technology, the RC delay becomes the dominant factor. To facilitate further improvements, semiconductor IC manufacturers have been forced to resort to new materials utilized to reduce the RC delay by either lowering the interconnect wire resistance, or by reducing the capacitance of the ILD. A significant improvement was achieved by replacing the aluminum (Al) interconnects with copper. Further advances are facilitated by the change of the low-k dielectric materials.

Industry publications have indicated that low-k materials with dielectric constant k values from 2.7 to 3.5 would be needed for 150 and 130 nm technology modes. When the industry moves to 100 nm technology and dimensions below that in the future, extra low-k (ELK) materials having a k value from 2.2 to 2.6 and ultra low-k (ULK) materials with a k value less than 2.2 will be necessary. However, general dielectric materials with a k value less than 2.5 are sloppy structures with pores, and therefore the low-k materials have degraded properties, such as mechanical property, cohesive strength or interfacial adhesion. In general, the interfacial adhesion energies less than 5 J/m² will exhibit delamination or cracking under external energies or forces in post-treatments, such as polishing process, which seriously influences the electrical performance or reliability of semiconductor devices.

Please refer to FIG. 1, which is a scanning electron microscopy (SEM) diagram of an ultra low-k dielectric film ULK according to the prior art. As the circular mark shows, the prior-art ultra low-k dielectric film ULK occurs deplamination problems under a polishing process, such that the electrical performance of the semiconductor device is reduced. Accordingly, to provide a low-k dielectric film with better mechanical or chemical properties is still an important issue for semiconductor manufacturers.

### SUMMARY OF THE INVENTION

It is therefore a primary objective of the claimed invention to provide a porous low-k dielectric film fabricated by a two-step time delay method to solve the above-mentioned cracking or delamination problems resulting in degraded cohesive strength or low interfacial adhesion.

According to the claimed invention, the method for fabricating a porous low-k dielectric film comprises providing a substrate, performing a first CVD process by providing a back-bone precursor into a deposition chamber so as to form an interface dielectric layer on the substrate, and performing a second CVD process by providing a porogen precursor into the depositing reactor while the back-bone precursor is continuously provided into the depositing reactor so that the porogen precursor and the back-bone precursor jointly form a back-bone layer on the interface dielectric layer, wherein the back-bone layer comprises a porogen material distributed in the back-bone layer. The claimed invention method further comprises removing the porogen material for leaving a plurality of pores in the back-bone layer to form an ultra low-k (ULK) layer. The interface dielectric layer and the ultra low-k layer compose a porous low-k film.

According to the claimed invention, a porous low-k film is further provided. The porous low-k film comprises an interface dielectric layer and an ultra low-k layer positioned on the interface dielectric layer. The ultra low-k layer includes a plurality of pores, and the pore density of the ultra low-k layer is more than the pore density of the interface dielectric layer.

It is an advantage of the claimed invention that the interface dielectric layer with a high cohesive strength is first formed on the substrate so that the interface dielectric layer can effectively adhere to the ultra low-k layer and the substrate. Accordingly, a porous low-k film with a preferable structure and a preferable mechanical property is provided such that the delamination and cracking problem can be avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an SEM diagram of an ultra low-k dielectric film ULK according to the prior art.

FIG. 2 to FIG. 6 are schematic diagrams of the method for fabricating a porous low-k film according to the present invention.

FIG. 7 is a schematic diagram of the porous low-k film according to a second embodiment of the present invention.

FIG. 8 is an SEM diagram of the present invention porous low-k film.

FIG. 9 is a timing diagram of a first CVD process and a second CVD process according to the present invention.

FIG. 10 is a process diagram of forming the present invention porous low-k film.

### DETAILED DESCRIPTION

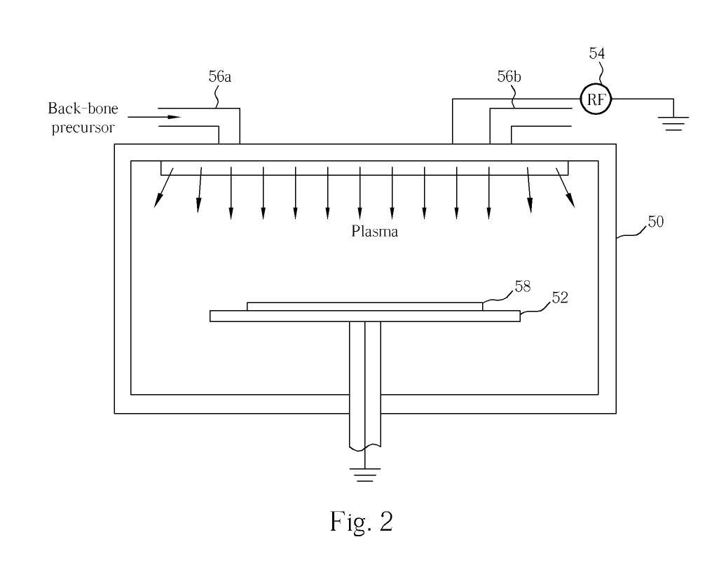

With reference to FIG. 2 to FIG. 6, which are schematic diagrams of the method for fabricating a porous low-k film according to the present invention. As shown in FIG. 2, a substrate 58 having semiconductor materials is provided, wherein the semiconductor materials comprises silicon substrate, silicon-on-insulator (SOI) substrate, or substrates with silicon germanium or silicon carbon material. Then, the substrate 58 is delivered to a deposition chamber 50 for performing CVD processes. In this embodiment, the deposition chamber 50 is a PECVD chamber, containing a substrate chuck 52 for positioning the substrate 58 and two furnaces 56a, 56b for introducing reaction gases.

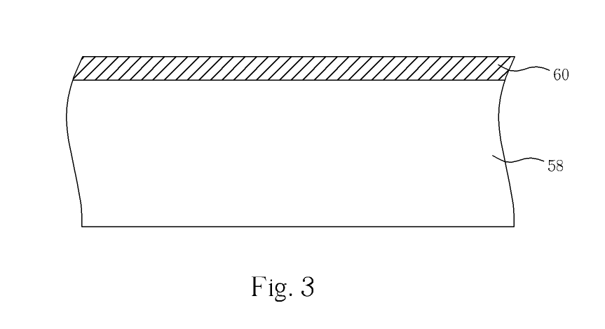

A first CVD process is performed by introducing a back-bone precursor into the deposition chamber 50 through the furnace 56a, wherein the first CVD process is preferably a PECVD process. FIG. 3 shows an enlarged section-view of the substrate 58 shown in FIG. 2. As shown in FIG. 3, during the first CVD process, the back-bone precursor forms an interface dielectric layer 60 with a dense structure on the substrate 58. The back-bone precursor preferably comprises organosilicate materials. Since organosilicate materials are liquid, the back-bone precursor is delivered by a liquid system while an inert gas, such as helium or argon, is used as the carry gas of the organosilicate materials when they are introduced into the deposition chamber 50. Therefore, the interface dielectric layer 60 with carbon, silicon, and oxygen atoms comprises carbon-doped oxide (CDO) material.

The process parameter of the first CVD process is listed below: A high frequency radio frequency (HFRF) and a low frequency radio frequency (LFRF) are continuously provided during the first CVD process, represented by the RF power 54 in FIG. 2. The power of the HFRF ranges from about 50 to 6000 watt, preferably from about 600 to 1500 watt. The power of the LFRF ranges from about 0 to 2500 watt, preferably from about 0 to 800 watt while the low frequency of the LFRF is in a range of about 350 to 450 Hz. The process temperature is about 150° C. to 450° C. In addition, before depositing the interface dielectric layer 60, the pressure of the deposition chamber 50 is about 1.0 torr to 15 torr.

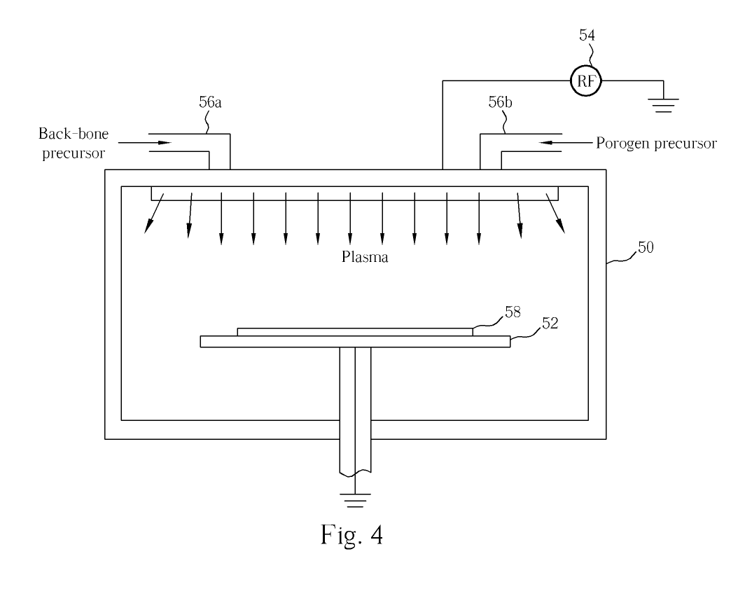

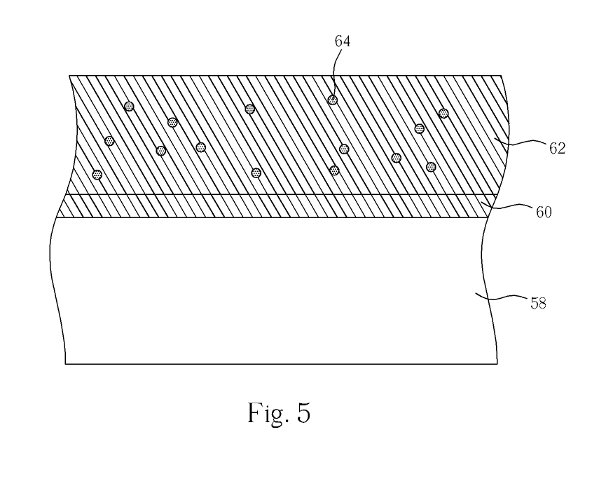

After the back-bone precursor is introduced into the deposition chamber 50 for a predetermined time, a second CVD process is started, wherein the predetermined time is about 1 to 30 sec, preferable about 1 to 10 sec. Please refer to FIG. 4, a porogen precursor (or pore generation precursor) is in-situ introduced into the deposition chamber 50 by the furnace 56b while the back-bone precursor is continuously provided so as to perform a PECVD process. During the PECVD process, the porogen precursor and the back-bone precursor jointly form a back-bone layer 62, as shown in FIG. 5. The porogen precursor comprises CₓH_{y} components. Since the back-bone precursor and the porogen precursor are simultaneously introduced into the deposition chamber 50, the back-bone layer 62 comprises a porogen material 64 with CₓH_{y} components distributed in the back-bone layer 62. In this embodiment, the process time of the second CVD process is about 1 to 30 sec, preferably about 1 to 10 sec. The thickness of the back-bone layer 62 is more than the thickness of the interface dielectric layer 60.

During the second CVD process, the above-mentioned HFRF and LFRF are continuously provided. The power of the HFRF is about 50 to 6000 watt, preferably about 600 to 1500 watt; the power of the LFRF is about 0 to 2500 watt, preferably about 0 to 800; and the low frequency of the LFRF is about 350 to 450 Hz. The process temperature of the second CVD process is about 150° C. to 450° C., and the pressure of the deposition chamber 50 is in a range of about 1.0 to 20 torr. In addition, the carry layer of the porogen precursor can be the same as that of the back-bone precursor such that an inert gas, such as helium or argon, is taken as the carry layer, wherein the flow rate of the carry layer is about 100 to 20000 stand cubic centimeters per minute (sccm), preferably 3000 to 10000 sccm.

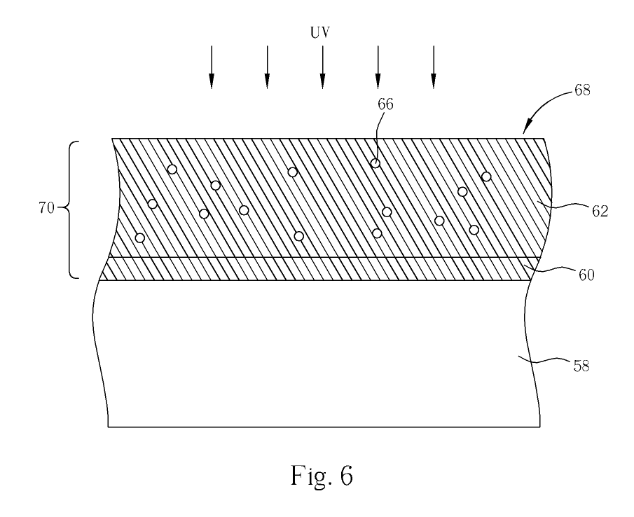

Referring to FIG. 6, a post-treatment to the back-bone layer 62 is performed for removing the porogen material 64 in the back-bone layer 62. The post-treatment comprises performing a thermal baking process, an e-beam curing process, or an UV curing process. In FIG. 6, the UV process is illustrated for explanation. After the porogen material 64 is removed, a plurality of pores 66 are left in the back-bone layer 62 so that a porous ultra low-k layer 68 is formed. Accordingly, the pore density of the ultra low-k layer 68 is more than that of the interface dielectric layer 60. The interface dielectric layer 60 and the ultra low-k layer 68 compose a porous low-k film 70 having a dielectric constant of about 1.0 to 2.7, which can be applied to metal-layer dielectric (ILD) or ILD structures for decreasing RC delay effects.

It is an advantage that the interface dielectric layer 60 has a dense structure with preferable cohesive strength and interfacial adhesion so that the ultra low-k layer 68 can be effectively attached to the substrate 58 through the interface dielectric layer 60. Accordingly, a porous low-k film 70 with a preferable chemical property or mechanical property is provided to prevent cracking or delamination problems under an external force during following processes, such as chemical polishing (CMP) process.

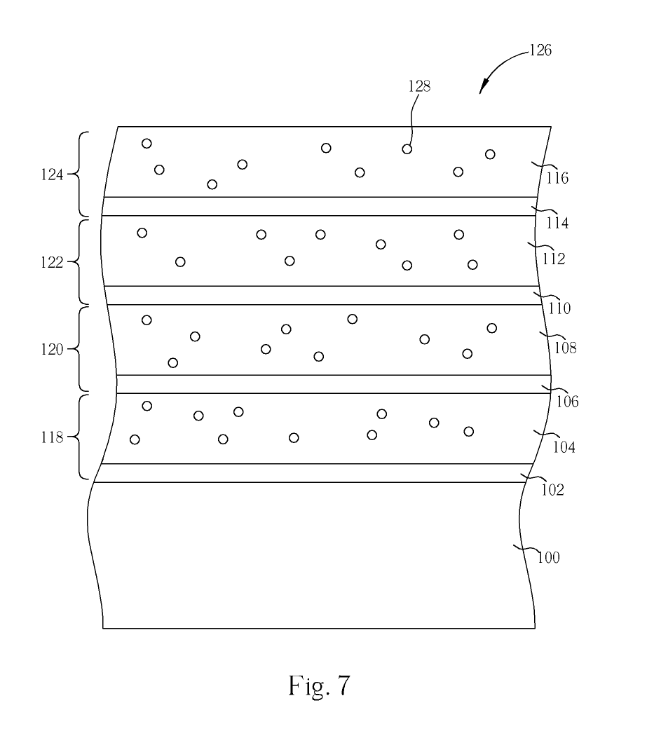

Pleaser refer to FIG. 7. FIG. 7 is a schematic diagram of the porous low-k film according to a second embodiment of the present invention. In this embodiment, a CVD reactor with four stages is employed for fabrication the present invention porous low-k film. Therefore, the above-mentioned first CVD process and second CVD process are repeated four times to form a stacked structure comprising interface dielectric layers and ultra low-k layers disposed alternately.

As shown in FIG. 7, a substrate 100 with semiconductor materials is first provided in a first stage of the CVD reactor. A first CVD process and a second CVD process are performed in sequence in the first stage. In the first CVD process, a back-bone precursor is first provided for about 1 to 30 sec, preferably 1 to 10 sec, so as to form a first interface dielectric layer 102 on the substrate 100. Sequentially, a porogen precursor is provided while the back-bone precursor is continuously provided so that the porogen precursor and the back-bone precursor jointly form a first back-bone layer 104 with porogen materials. Accordingly, a first low-k layer 118 is formed. Then, the substrate 100 is delivered to the second stage, and the above-mentioned first and second CVD process are repeated to form a second interface dielectric layer 106 and a second back-bone layer 108 respectively so as to form a second low-k layer 120. Similarly, the substrate 100 is delivered to the third stage and the fourth stage sequentially. In the third stage and the fourth stage, the first and second CVD processes are performed individually to form a third low-k layer 122 comprising a third interface dielectric layer 110 and a third back-bone layer 112 and a fourth low-k layer 124 comprising a fourth interface dielectric layer 114 and a fourth back-bone layer 116. Finally, an UV curing process, a thermal baking process, or a e-beam curing process is performed to the materials on the substrate 100 for removing the porogen material so that the first, second, third, and fourth back-bone layer 104, 108, 112, 116 become to ultra low-k layers with pluralities of pores 128. Therefore, a porous low-k film 126 with four stacked low-k layers is fabricated, wherein its dielectric constant is in a range of about 1.0 to 2.7. The interface dielectric layers (102, 106, 110, 114) and the ultra low-k layers (104, 108, 112, 116) are stacked alternately. However, in other embodiments, the process of removing the porogen material can be performed after each stage of the CVD processes according to design or process requirement.

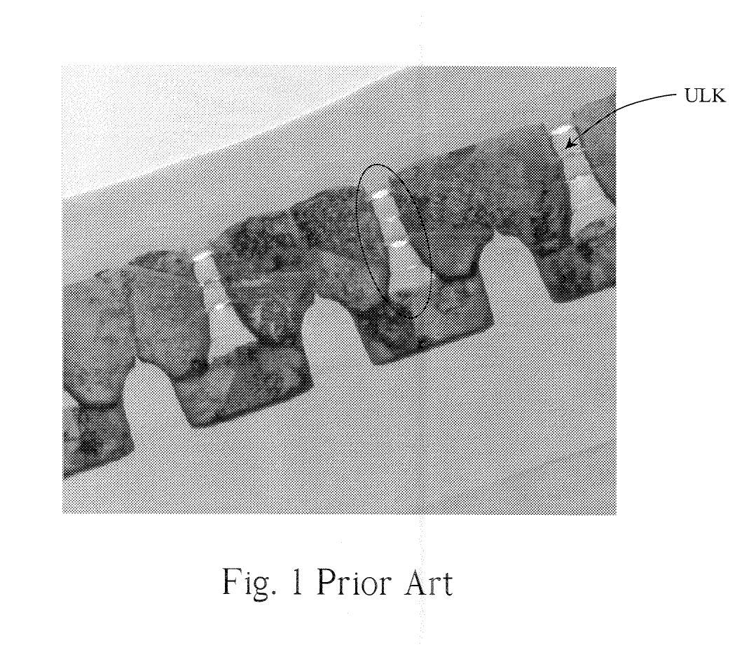

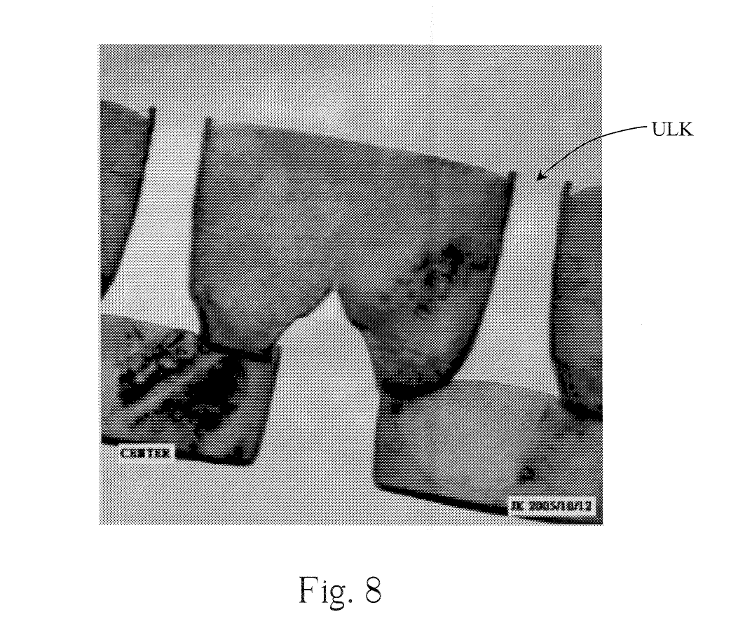

With reference to FIG. 8, FIG. 8 is an SEM diagram of the present invention porous low-k film. The present invention porous low-k film ULK with ultra low-k layers is pointed by an arrow in FIG. 8. The fabrication process of the present invention porous low-k film ULK employs a four stages CVD reactor to form four low-k layers, as described in the second embodiment of the present invention. In comparison with the prior-art low-k film shown in FIG. 1, those skilled in the art can clearly understand that the present invention porous low-k film ULK has a good structure after a polishing process. Accordingly, the present invention porous low-k film ULK has a preferable mechanical property so that the structure will not easily occur delamination or cracking problems even under CMP, etching or dicing process. As a result, a preferable dielectric performance can be provided.

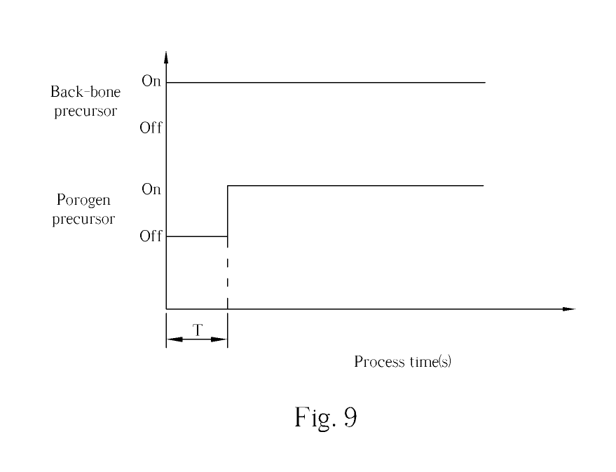

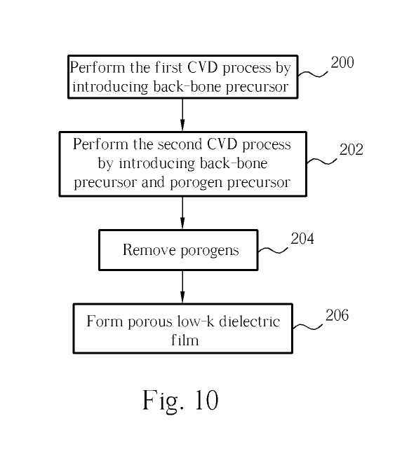

Please refer to FIG. 9 and FIG. 10, wherein FIG. 9 is a timing diagram of the first CVD process and the second CVD process according to the present invention, and FIG. 10 is a process diagram of forming the present invention porous low-k film. FIG. 10 is described as below:

Step 200: Perform a first CVD process by introducing a back-bone precursor continuously into a deposition chamber for a predetermined time T to form an interface dielectric layer with good cohesive strength, interfacial adhesion, and mechanical property, and no porogen precursor is provided during the predetermined time.

Step 202: After the predetermined delay time T, perform a second CVD process by introducing a porogen precursor into the deposition chamber so as to form the back-bone layer containing a porogen material together with the back-bone precursor.

Step 204: Perform a post-treatment to the back-bone layer in order to remove the porogen material and leave pores in the back-bone layer.

Step 206: After the post-treatment, the back-bone layer becomes to an ultra low-k later, and the ultra low-k layer and the interface dielectric layer are defined as a porous low-k film.

It should be noted that a plurality of back-bone precursors and prorogen precursors may be adopted in the present invention. For example, the back-bone precursor may contain various kinds of organosilicate materials, and the porogen precursor may contain different kinds of hydrocarbon components. In addition, the present invention can be applied to “single-stage” CVD reactors or “multi-stage” CVD reactors provided that the porogen precursor is delayed a predetermined time after the back-bone precursor is provided in the CVD process so that an interface dielectric layer and a ultra low-k layer are formed in sequence.

In contrary to the prior art, the present invention provides a two-step time delay method with a non-broken chamber process by delaying the introduction of the porogen precursor a predetermined time in comparison with the deposition chamber. As a result, an interface dielectric layer with good cohesive strength and interfacial adhesion is first fabricated and a back-bone layer with porogen material is formed on the interface dielectric layer after the introduction of the porogen precursor. After removing the porogen material, an ultra low-k layer can be formed. Accordingly, the ultra low-k layer can be closely attached to the substrate by the interface dielectric layer so that the whole porous low-k film has a good mechanical property even fabricated through a multi-stage CVD reactor. In addition, the present invention porous low-k film can be applied to any applications in needed of low-k materials, such as shallow trench isolation (STI) structures, ILD or IMD structure, such that the quality of semiconductor devices can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a porous low-k film comprising:
(a) providing a substrate;
(b) performing a first chemical vapor deposition (CVD) process by providing a back-bone precursor into a deposition chamber so as to form a interface dielectric layer on the substrate;
(c) performing a second CVD process by providing a porogen precursor into the depositing reactor while the back-bone precursor is continuously provided into the depositing reactor so that the porogen precursor and the back-bone precursor jointly form a back-bone layer on the interface dielectric layer, the back-bone layer comprising a porogen material distributed in the back-bone layer; and
(d) removing the porogen material in the back-bone layer for leaving a plurality of pores in the back-bone layer to form a ultra low-k (ULK) layer, the interface dielectric layer and the ultra low-k layer composing a porous low-k film.

2. The method of claim 1, wherein the back-bone precursor comprises organosilicate precursors.

3. The method of claim 2, wherein the interface dielectric layer comprises carbon-doped oxide (CDO) materials.

4. The method of claim 1, wherein the porogen precursor comprises CₓH_{y} components.

5. The method of claim 1, wherein the step of providing the porogen precursor is performed after the back-bone precursor is provided for about 1 to 30 seconds.

6. The method of claim 1, wherein the step of providing the porogen precursor is performed after after the back-bone precursor is provided for about 1 to 10 seconds.

7. The method of claim 1, wherein a time of providing the back-bone precursor and the porogen precursor during performing the second CVD process is about 1 to 30 seconds.

8. The method of claim 1, wherein a time of providing the back-bone precursor and the porogen precursor during performing the second CVD process is about 1 to 10 seconds.

9. The method of claim 1, wherein the method further comprises repeat the step (b) and the step (c) a plurality of times by turns to form a plurality of the porous low-k films comprising a plurality of the interface dielectric layers and the ultra low-k layers alternately on the substrate.

10. The method of claim 1, wherein an inert gas is used as a carrier gas of the back-bone precursor or the porogen precursor during the second CVD process.

11. The method of claim 10, wherein a flow rate of the carrier gas ranges about 100 to 20000 standard cubic centimeters per minute (sccm).

12. The method of claim 10, wherein a flow rate of the carrier gas is in a range of about 3000 to 10000 sccm.

13. The method of claim 1, wherein a process temperature of the (b) step or the (c) step is about 150° C. to 450° C.

14. The method of claim 1, wherein a pressure of the deposition chamber is about 1.0 to 15 torr before forming the interface dielectric layer.

15. The method of claim 1, wherein a pressure of the deposition chamber is about 1.0 to 20 torr during the second CVD process.

16. The method of claim 1, wherein a high frequency radio frequency (HFRF) and a low frequency radio frequency (LFRF) are provided to the deposition chamber during the first and the second CVD processes.

17. The method of claim 16, wherein a power of the HFRF ranges from about 50 to 6000 W.

18. The method of claim 16, wherein a power of the HFRF ranges from about 600 to 1500 W.

19. The method of claim 16, wherein a power of the LFRF ranges from about 0 to 2500 W.

20. The method of claim 16, wherein a power of the LFRF ranges from about 0 to 800 W.

21. The method of claim 16, wherein a frequency of the LFRF is in a range of about 350 to 450 Hz.

22. The method of claim 1, wherein the step of removing the porogen materials comprises a thermal baking process, an e-beam process, or an UV curing process.

23. The method of claim 1, wherein a dielectric constant of the ultra low-k layer is in a range of about 1.0 to 2.7.

24. The method of claim 1, wherein the first and the second CVD processes are plasma-enhanced CVD (PECVD) processes.

25. A porous low-k film, comprising:
an interface dielectric layer; and
an ultra low-k layer positioned on the interface dielectric layer, the ultra low-k layer comprising a plurality of pores, a pore density of the ultra low-k layer being more than a pore density of the interface dielectric layer.

26. The porous low-k film of claim 25, wherein a thickness of the ultra low-k layer is larger than a thickness of the interface dielectric layer.

27. The porous low-k film of claim 25, wherein the interface dielectric layer and the ultra low-k layer comprise CDO materials.

28. The porous low-k film of claim 25, wherein the porous low-k film comprises a plurality of the interface dielectric layers and the ultra low-k layers stacked alternately.

29. The porous low-k film of claim 25, wherein a dielectric constant of the ultra low-k layer is in a range of about 1.0 to 2.7.
